(19) United States
(12) Patent Application Publication
(10) Pub. No.: US 2022/0050372 A1
(43) Pub. Date: Feb. 17, 2022

(54) MASK BLANK, TRANSFER MASK, AND METHOD FOR MANUFACTURING SEMICONDUCTOR DEVICE

(71) Applicant: HOYA CORPORATION, Tokyo (JP)

(72) Inventors: Hiroyuki ISHIDA, Tokyo (JP); Takeshi AIZAWA, Tokyo (JP)

(73) Assignee: HOYA CORPORATION, Tokyo (JP)

(21) Appl. No.: 17/275,413

(22) PCT Filed: Sep. 4, 2019
(86) PCT No.: PCT/JP2019/034704

§ 371 Date: Mar. 11, 2021

(30) Foreign Application Priority Data
Sep. 12, 2018 (JP) 2018-170715

(51) Int. Cl. G03F 1/32

(52) U.S. Cl. CPC G03F 1/32

(57) ABSTRACT

Provided is a mask blank wherein, even when a defect is present on the main surface of a substrate of the mask blank, the defect can be made to not affect a transfer image formed by a transfer mask, such that the mask blank is deemed acceptable. This mask blank is provided with a thin film that is for transfer pattern formation and provided on the main surface of a transparent substrate, wherein a defect is present on the main surface of the transparent substrate, and the defect satisfies the relationship L≤97.9×w^{-0.4}, where w is the width as viewed from the main surface side, and L is the length from the main surface to the tip of the defect in a direction perpendicular to the main surface.

### CROSS-REFERENCE TO RELATED APPLICATIONS

This application is a National Stage of International Application No. PCT/JP2019/034704, filed Sep. 4, 2019, which claims priority to Japanese Patent Application No. 2018-170715, filed Sep. 12, 2018, and the contents of which is incorporated by reference.

### TECHNICAL FIELD

This disclosure relates to a mask blank, a transfer mask, and a method for manufacturing a semiconductor device.

### BACKGROUND ART

In a manufacturing process of a semiconductor device, a fine pattern is formed using a photolithography method. In forming the fine pattern, a transfer mask is used. Generally, the transfer mask has a fine transfer pattern which is formed on a transparent glass substrate and which comprises a metal thin film or the like. In manufacture of the transfer mask, the photolithography method is used also.

In recent years, with a progress in miniaturization of a pattern of the semiconductor device, miniaturization of a mask pattern formed on the transfer mask is advancing. Typically, the transfer mask is manufactured by using a mask blank having a substrate and a pattern-forming thin film formed on the substrate. The transfer mask is set on a mask stage of an exposure apparatus and irradiated with exposure light such as an ArF excimer laser. By the exposure light transmitted through a thin film pattern (transfer pattern) of the transfer mask, the pattern is transferred onto a transfer object (such as a resist film on a wafer).

Generally, in case where a defect is present on a substrate of a transfer mask, when exposure transfer is carried out onto a resist film on a wafer by using the transfer mask, there occurs a phenomenon that an image of the defect is transferred onto the resist film. Therefore, after the transfer mask is manufactured from a mask blank, mask defect inspection is carried out by a mask defect inspection apparatus. On the other hand, also in the mask blank as an original plate for manufacturing the transfer mask, it has always been desired that no defect is present on a substrate, in particular, in a region where the transfer pattern is to be formed. Therefore, in the mask blank also, inspection for a defect, for example, occurring in a manufacturing process of the mask blank, has heretofore been carried out (see Patent Document 1 and so on).

### PRIOR ART DOCUMENT(S)

### Patent Document(s)

Patent Document 1: JP 2010-175660 A

### SUMMARY OF THE DISCLOSURE

### Problem to be Solved by the Disclosure

However, in recent years, there is a remarkable improvement in performance of the defect inspection apparatus for carrying out defect inspection of the mask blank and it becomes possible to detect a defect of a size which could not be detected in the past. Therefore, a ratio of mask blanks with defects detected during the defect inspection becomes higher than that in the past. If only those mask blanks having no defect on their substrates are selected in a defect inspection step in manufacture of the mask blanks, there is a problem that a production yield significantly decreases.

The present inventors formulated a hypothesis that, even if a defect is present on a substrate (a main surface of the substrate) of a transfer mask, the defect may not be detected in mask defect inspection, depending on a condition of the defect. Furthermore, the present inventors formulated a hypothesis that, even if the defect is present on the substrate, a problem of an effect on a transferred image may not be caused depending on the condition of the defect. Alternatively, the present inventors formulated a hypothesis that the effect may be so small as to fall within an allowable range. Furthermore, the present inventors verified those hypotheses to obtain certain knowledge.

First, it is an aspect of this disclosure to provide a mask blank capable of being deemed as an acceptable product assuming that, even if a defect is present on a main surface of a substrate of the mask blank, the defect has no effect on a transferred image by a transfer mask.

Second, it is an aspect of this disclosure to provide a transfer mask capable of being deemed as an acceptable product assuming that, even if a defect is present on a main surface of a substrate of the transfer mask, the defect has no effect on a transferred image by the transfer mask.

Third, it is an aspect of this disclosure to provide a method for manufacturing a high-quality semiconductor device formed with a fine pattern by using the above-mentioned transfer mask.

### Means to Solve the Problem

In order to solve the above-mentioned problem, the present inventors tried to conduct the following studies.

Those defects detected by a defect inspection apparatus and, for example, present on a substrate of a transfer mask are different in shape, size in planar view, and height. The present inventors formulated a hypothesis that, even if a defect is present on a substrate (a main surface of the substrate) of a transfer mask, the defect may not be detected in mask defect inspection, depending on a condition of the defect. Furthermore, the present inventors formulated a hypothesis that, even if the detect which is not detected by the mask defect inspection is present on the substrate of the transfer mask, when exposure transfer is carried out onto a resist film on a wafer by using the transfer mask, an image of the defect may not be transferred onto the resist film and no effect of the defect appears on the resist film when a resist pattern is formed via a development process and so on. Alternatively, the present inventors formulated a hypothesis that, even if the defect is transferred onto the resist film, an effect of the defect on a pattern accuracy when the resist pattern is formed via the development process and so on may be so small as to fall within an allowable range.

In order to verify these hypotheses, the present inventors manufactured a programmed mask in which a large number of convex defects (programmed defects), different in size and height, are placed on a main surface of a substrate. By using a mask defect inspection apparatus Teron (manufactured by KLA Tencor), the programmed mask was subjected to verification of detection/non-detection of those convex defects. Furthermore, by using AIMS193 (manufactured by Carl Zeiss), the programmed mask was subjected to simulation of a transferred image when exposure transfer was carried out by using the programmed mask, to verify effects of those defects on the transferred image. As a result, it has been found out that any convex defect which was not detected by mask defect inspection had little effect on the transferred image and caused no substantial problem. Thus, it has been found out that the convex defects which were not detected by the mask defect inspection, even if actually present, caused no problem of the effect on the transferred image.

Furthermore, based on those verification results, the present inventors ascertained that, in each convex defect which is present on the substrate of the transfer mask and which is not detected by the mask defect inspection, a relationship between the width and the height of the convex defect satisfies a predetermined relationship.

As a result of further studies, the present inventors reached a conclusion that, even if any defect having the width and the height which satisfy the predetermined relationship is present on a substrate of a mask blank, the mask blank can be deemed as an acceptable product assuming that the defect has no effect on a transferred image. Thus, the disclosure having the following structures has been completed.

(Structure 1)

A mask blank comprising a transparent substrate having a main surface on which a thin film for forming a transfer pattern is formed, wherein:

a defect is present on the main surface of the transparent substrate; and

the defect satisfies a relationship:

L≤97.9×w^{-0.4}

where w represents a width of the defect as seen from the side of the main surface and L represents a length of the defect from the main surface to an end of the defect in a direction that is perpendicular to the main surface.

(Structure 2)

The mask blank according to Structure 1, wherein the length L of the defect is 13 nm or less.

(Structure 3)

The mask blank according to Structure 1 or 2, wherein the width w of the defect is 200 nm or less.

(Structure 4)

The mask blank according to any one of Structures 1 to 3, wherein the defect is present on the main surface of the transparent substrate in a region where a transfer pattern is to be formed on the thin film.

(Structure 5)

The mask blank according to any one of Structures 1 to 4, wherein the defect contains silicon and oxygen.

(Structure 6)

The mask blank according to any one of Structures 1 to 5, wherein the thin film has a function of transmitting exposure light of an ArF excimer laser at a transmittance of 2% or more and a function of causing the exposure light having been transmitted through the thin film to have a phase difference of 150 degrees or more and 200 degrees or less with respect to exposure light having passed through air for the same distance as a thickness of the thin film.

(Structure 7)

A transfer mask comprising a transparent substrate having a main surface on which a thin film formed with a transfer pattern is provided, wherein:

a defect is present on the main surface of the transparent substrate; and

the defect satisfies a relationship:

L≤97.9×w^{-0.4}

where w represents a width of the defect as seen from the side of the main surface and L represents a length of the defect from the main surface to an end of the defect in a direction that is perpendicular to the main surface.

(Structure 8)

The transfer mask according to Structure 7, wherein the length L of the defect is 13 nm or less.

(Structure 9)

The transfer mask according to Structure 7 or 8, wherein the width w of the defect is 200 nm or less.

(Structure 10)

The transfer mask according to any one of Structures 7 to 9, wherein the defect is present on the main surface of the transparent substrate in a region where a transfer pattern is formed on the thin film.

(Structure 11)

The transfer mask according to any one of Structures 7 to 10, wherein the defect contains silicon and oxygen.

(Structure 12)

The transfer mask according to any one of Structures 7 to 11, wherein the thin film has a function of transmitting exposure light of an ArF excimer laser at a transmittance of 2% or more and a function of causing the exposure light having been transmitted through the thin film to have a phase difference of 150 degrees or more and 200 degrees or less with respect to exposure light having passed through air for the same distance as a thickness of the thin film.

(Structure 13)

A method for manufacturing a semiconductor device, comprising a step of exposure-transferring a transfer pattern onto a resist film on a semiconductor substrate by using the transfer mask according to any one of Structures 7 to 12.

### Effect of the Disclosure

According to this disclosure, it is possible to provide a mask blank capable of being deemed as an acceptable product assuming that, even if a defect is present on a main surface of a substrate of the mask blank, the defect has no effect on a transferred image by a transfer mask.

According to this disclosure, it is also possible to provide a transfer mask capable of being deemed as an acceptable product assuming that, even if a defect is present on a main surface of a substrate of the transfer mask, the defect has no effect on a transferred image by the transfer mask.

Furthermore, it is possible to manufacture a high-quality semiconductor device formed with a fine pattern by using a transfer mask obtained by this disclosure.

### BRIEF DESCRIPTION OF THE DRAWINGS

FIG. 1 is a schematic sectional view of a mask blank;

FIG. 2 is a sectional view of a mask blank substrate:

FIG. 3 is a schematic sectional view of a transfer mask;

FIG. 4 is a plan view for illustrating a structure of programmed defects;

FIG. 5 is a sectional view for illustrating the structure of the programmed defects; and

FIG. 6 is a view for illustrating a verification result when a plurality of programmed masks each having a large number of convex defects (programmed defects) placed on a main surface of a substrate are subjected to verification of detection/non-detection of the convex defects by a mask defect inspection apparatus Teron.

### MODE FOR EMBODYING THE DISCLOSURE

Now, a mode for embodying this disclosure will be described in detail with reference to the drawings.

As described above, the present inventors formulated a hypothesis that, even if a defect is present on a substrate (a main surface of the substrate) of a transfer mask, the defect may not be detected in mask defect inspection, depending on a condition of the defect. Furthermore, the present inventors formulated a hypothesis that, even if the defect is present, a problem of an effect on a transferred image may not be caused or the effect may be so small as to fall within an allowable range, depending on the condition of the defect. Furthermore, the present inventors verified those hypotheses and completed this disclosure based on obtained knowledge. Hereinafter, detailed description will be made.

The present inventors formulated a hypothesis that, even if a defect is present on a substrate (a main surface of the substrate) of a transfer mask, the defect may not be detected in mask defect inspection, depending on a condition of the defect. Furthermore, the present inventors formulated a hypothesis that, even if the detect which is not detected by the mask defect inspection is present on the substrate of the transfer mask, when exposure transfer is carried out onto a resist film on a wafer (semiconductor substrate) by using the transfer mask, an image of the defect may not be transferred onto the resist film and no effect of the defect appears on the resist film when a resist pattern is formed via a development process and so on. Alternatively, the present inventors formulated a hypothesis that, even if the defect is transferred onto the resist film, an effect of the defect on a pattern accuracy when the resist pattern is formed via the development process and so on may be so small as to fall within an allowable range.

In order to verify these hypotheses, the present inventors manufactured a plurality of programmed masks. In each programmed mask, a large number of convex defects (programmed defects) are placed on a main surface of a substrate. The large number of convex defects placed on one programmed mask are substantially same in height. However, the large number of convex defects are different in size (size (for example, width) as seen from a main surface side (i.e., in planar view)). In the one programmed mask, a line-and-space thin film pattern (transfer pattern) is placed on the large number of convex defects. Furthermore, the heights of the convex defects are different between the respective programmed masks.

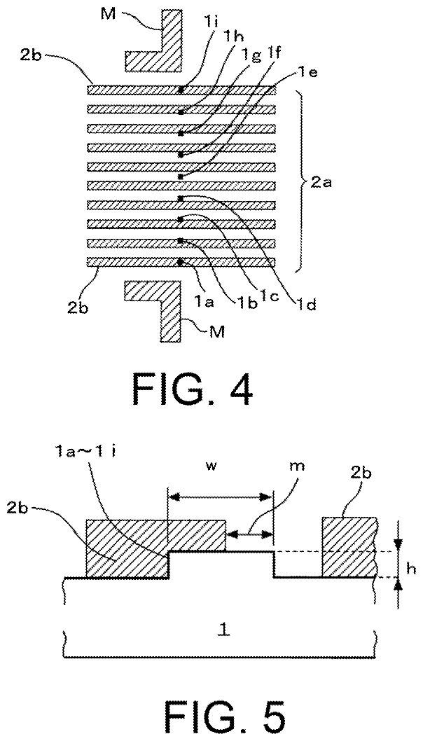

FIG. 4 is a plan view for illustrating a structure of the programmed defects formed in each programmed mask. FIG. 5 is a sectional view for illustrating the structure of the programmed defects.

As illustrated in FIGS. 4 and 5, on a main surface of a substrate (glass substrate) 1, a plurality of (nine) convex defects, same in size (width) and height, are placed at equal intervals. On the nine convex defects 1a, 1b, . . . , 1h, 1i (hereinafter may be represented as 1a to 1i) same in size and height and placed at the equal intervals, a line-and-space thin film pattern (transfer pattern) 2a having line patterns 2b slightly different in interval from the convex defects 1a to 1i is placed. This bring about a state where overlapping degrees between the convex defects 1a to 1i and the line patterns 2b are different. In the programmed defects, the state of the different overlapping degrees between the convex defects and the line patterns is formed with respect to every convex defects of different sizes (with substantially same heights). One programmed mask is provided with the programmed defects same in height of the convex defects. Thus, different programmed masks are manufactured for every programmed defects different in height of the convex defects.

As a specific example of the programmed defects, for example, a plurality of convex defects having different sizes (widths) w in a range of 32 nm to 200 nm and substantially same heights h (in a range of 4 nm to 24 nm) are placed. On the convex defects, the line-and-space thin film pattern (transfer pattern) 2a having a pitch of 360 nm is placed and overlapping degrees (width m shown in FIG. 5) between the convex defects 1a to 1i and the line patterns 2b are controlled. In FIG. 4, L-shaped marks M are provided so as to allow the mask defect inspection apparatus to easily detect positions of the programmed defects on the programmed mask during mask defect inspection.

In case where a transfer mask is manufactured from a mask blank with convex defects present on a transparent substrate, positional relationships between the thin film pattern of the completed transfer mask and the convex defects (overlapping degrees between pattern edges and the convex defects) may be put into various states, depending on the shape of the pattern formed on a pattern-forming thin film of the mask blank and on a layout of the pattern on the main surface. By carrying out verification by the mask defect inspection apparatus Teron and AIMS 193 using the programmed defects such that the overlapping degrees between the line pattern of the thin film and the convex defects are different as described above, it is possible to identify a range of the convex defects such that, irrespective of the positional relationship between the thin film pattern and the convex defects, the convex defects are not detected in the mask defect inspection and an effect of the convex defects on a transferred image when carrying out exposure transfer is not caused or the effect falls within an allowable range.

The above-mentioned programmed defects can be prepared by the following method.

At first, convex defects different in size are formed on a glass substrate, for example, by an etching method. Next, a pattern-forming thin film is formed throughout an entire surface of the substrate. Thereafter, by a photolithography method using a resist pattern, a predetermined line-and-space thin film pattern is formed. Thus, the programmed defects are prepared such that the state of different overlapping degrees between the convex defects and the line pattern is formed with respect to every convex defects of different sizes. The height of the convex defects is adjusted by an etching time for the glass substrate, or the like.

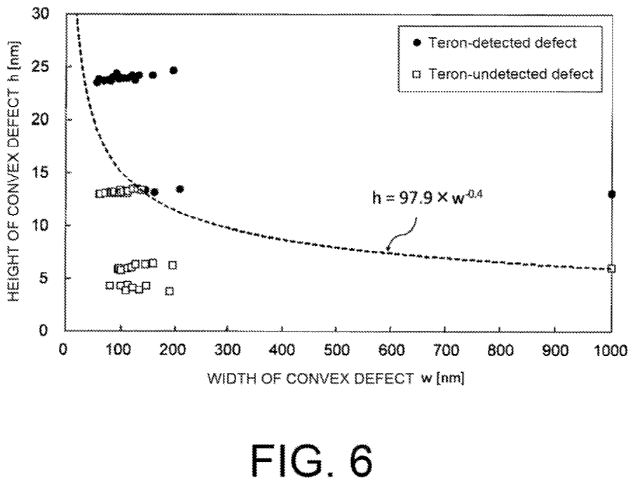

Next, by using the mask defect inspection apparatus Teron (manufactured by KLA Tencor), a plurality of programmed masks with the programmed defects placed therein were subjected to verification of detection/non-detection of the respective convex defects. As a result, it has been found that predetermined convex defects could not be detected. FIG. 6 is a view for illustrating a verification result when the plurality of the programmed masks with the programmed defects, different in size (width) and same in height, placed therein were subjected to verification of detection/non-detection of the respective convex defects by the mask defect inspection apparatus Teron.

Furthermore, by AIMS 193 (manufactured by Carl Zeiss), the plurality of programmed masks were subjected to simulation of transferred images when exposure transfer was carried out by using the programmed masks, to verify effects of the respective convex defects on the transferred images. As a result, it has been found out that there exist the convex defects having large effects on the transferred images to cause a problem and the convex defects having small effects on the transferred images to cause no substantial problem.

As a result of checking those verified data, it has been found out that any convex defect which could not be detected by the mask defect inspection had little effect on the transferred image and caused no substantial problem. Thus, it has been revealed that those convex defects which cannot be detected by the mask defect inspection, although actually present, do not cause a problem of affecting the transferred image.

Furthermore, based on those verification results, the present inventors ascertained that, in a convex defect which is present on a substrate in a mask blank or a transfer mask and which is not detected by mask defect inspection, the relationship between the width w and the height h of the convex defect satisfies the relationship:

h≤97.9×w^{-0.4}.

In FIG. 6 mentioned above, a curve representing the relationship h≤97.9×w^{-0.4} is illustrated.

From the verification results mentioned above, the present inventors reached a conclusion that, even if convex defects satisfying the above-mentioned relationship between the width w and the height h are present on a substrate in a mask blank or a transfer mask, the mask blank or the transfer mask can be deemed as an acceptable product assuming that the convex defects have no effect on a transferred image. Thus, this disclosure has been completed.

In the foregoing, the verification result related to the convex defects is described. However, the similar conclusion holds also in case of concave defects.

A mask blank according to this disclosure comprises a transparent substrate having a main surface on which a thin film for forming a transfer pattern is formed, and is characterized in that a defect is present on the main surface of the transparent substrate; and the defect satisfies a relationship:

L≤97.9×w^{-0.4}

where w represents a width of the defect as seen from the side of the main surface and L represents a length of the defect from the main surface to an end of the defect in a direction that is perpendicular to the main surface.

Herein, the above-mentioned defects present on the main surface of the substrate include both the convex defects and the concave defects. The above-mentioned length L from the main surface to an end of the defect in a direction that is perpendicular to the main surface is the height h in case of the convex defects and the depth d in case of the concave defects. The above-mentioned defects present on the main surface of the substrate contain, for example, silicon and oxygen.

In the mask blank of this disclosure, the convex defects or the concave defects are present on the substrate of the mask blank. The convex defects or the concave defects satisfy a specific relationship (relational expression (1) between the above-mentioned width w and the above-mentioned length L of the defect) with which, when the transfer mask is manufactured using the mask blank and the transfer mask is subjected to mask defect inspection, the convex defects or the concave defects are not detected. Accordingly, the mask blank with the convex defects or the concave defects detected in a defect inspection step during manufacture of the mask blank can be deemed as an acceptable product assuming that, although the convex defects or the concave defects are present, these defects do not affect a transferred image if the convex defects or the concave defects satisfy the above-mentioned relational expression (1). Consequently, the ratio of the mask blanks deemed as acceptable products becomes higher so that the mask blanks are provided at a high yield.

In the mask blank according to this disclosure, the length L of the defect is preferably 13 nm or less. If the length L of the defect, i.e., the height h in case of the convex defect or the depth din case of the concave defect, exceeds 13 nm, such defect often fail to satisfy the above-mentioned relational expression (1) between the width w and the length L of the defect so that the effect on the transferred image becomes greater. More preferably, the length L of the defect is 11 nm or less. This is because, if the length L of the defect is 11 nm or less and the width w of the defect is 200 nm or less, the defect is not detected by the mask defect inspection. Further preferably, the length L of the defect is 6 nm or less. This is because, if the length L of the defect is 6 nm or less and the width w of the defect is 1000 nm or less, the defect is not detected by the mask defect inspection.

In the mask blank according to this disclosure, the width w of the defect is preferably 200 nm or less. If the width w of the defect exceeds 200 nm, such defect often fails to satisfy the relational expression (1) between the width w and the length L of the defect so that the effect on the transferred image becomes greater.

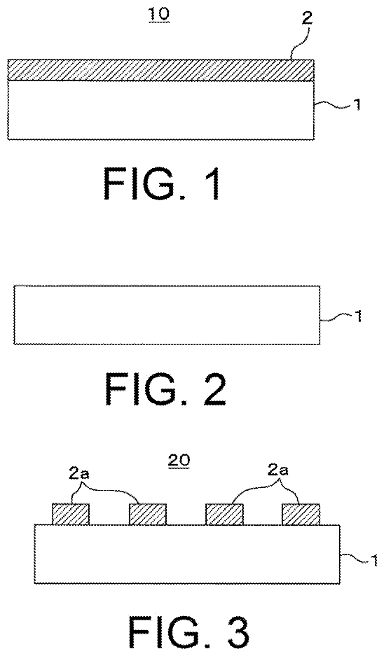

A mask blank according to this disclosure is a mask blank 10 having a transparent substrate 1 on which a thin film 2 for transfer pattern formation is formed on a main surface thereof (see FIG. 1, FIG. 2).

The transparent substrate 1 is not particularly restricted as far as the substrate is for use in a transfer mask (for example, a binary mask, a transmission-type mask such as a phase shift mask, and so on) for manufacture of a semiconductor device. Therefore, the transparent substrate 1 is not particularly limited as far as the substrate is transparent with respect to an exposure wavelength to be used. A synthetic quartz substrate and other glass substrates of various kinds (for example, soda lime glass, aluminosilicate glass, and so on) may be used. Among others, the synthetic quartz substrate is particularly preferably used because it is highly transparent with respect to an ArF excimer laser (wavelength of 193 nm) effective in fine pattern formation or in a shorter-wavelength region.

In case of a mask blank for manufacture of a transmission-type mask, a light-shielding film, a semi-transmissive film, a phase shift film, or a multilayer film comprising those films is used as the thin film 2. If the thin film 2 is the phase shift film, the thin film preferably has a function of transmitting, for example, exposure light of an ArF excimer laser (wavelength of 193 nm) at a transmittance of 2% or more and a function of causing the exposure light having been transmitted through the thin film to have a phase difference of 150 degrees or more and 200 degrees or less with respect to the exposure light having passed through air for the same distance as a thickness of the thin film. Depending on purposes, a hard mask film or an etching stopper film may be further added. The thin film 2 may be a single-layer film ora multilayer film comprising multiple films of the same kind or different kinds. As a material of the thin film 2, for example, a material containing chromium (Cr), a material containing silicon (Si), a material containing silicon (Si) and transition metal (such as Mo), a material containing tantalum (Ta) may be used, of course not being limited to those materials.

A method for forming the thin film 2 on the transparent substrate 1 such as the mask blank 10 illustrated in FIG. 1 need not be particularly limited. Among others, a sputtering film-forming method is preferably used. The sputtering film-forming method is preferable because a uniform film with a constant film thickness can be formed according to this method.

Even if the convex defects or the concave defects are detected in the defect inspection step during manufacture of the mask blank, the mask blank can be deemed as an acceptable product in defect inspection assuming that the defects do not affect the transferred image, in case where the defects satisfy the relational expression (1) between the width w and the length L of the defect. Thus, the ratio of the mask blanks as the acceptable products in the defect inspection becomes higher so that a production yield of the mask blanks can be improved.

In this disclosure, the above-mentioned defects are those defects present on the main surface of the transparent substrate in a region where the transfer pattern is to be formed on the thin film. Herein, in case where the substrate has a main surface of a square shape having a side of about 152 mm, the region where the transfer pattern is to be formed on the thin film is preferably an inside region of a square shape having a side of 132 mm with respect to a center of the main surface of the substrate as a reference. Therefore, even if the defects are present on the main surface of the substrate in the inside region of a square shape having a side of 132 mm with respect to the center of the main surface of the substrate as a reference, the mask blank can be judged as an acceptable product in the defect inspection in case where the defects satisfy the above-mentioned relational expression (1).

On the main surface of the transparent substrate 1 of the mask blank 10 according to this disclosure, the defects having the width w and the length L which do not satisfy the above-mentioned relational expression (1) can be present in an outside region around the region where the transfer pattern is to be formed on the thin film. This is because the outside region around the region where the transfer pattern is to be formed on the thin film 2 has no substantial effect on the transferred image. On one hand, all of the defects present on the main surface of the transparent substrate 1 of the mask blank 10 of this disclosure in the region where the transfer pattern is to be formed on the thin film 2 preferably satisfy the above-mentioned relational expression (1). On the other hand, if the defects having the width w and the length L which do not satisfy the above-mentioned relational expression (1) are present on the main surface of the transparent substrate 1 in the region where the transfer pattern is to be formed on the thin film 2, the number of the defects is small, and the transfer pattern can be arranged on the thin film 2 so as not to be affected by the defects, the mask blank can be deemed as an acceptable product.

On the main surface of the transparent substrate 1 of the mask blank 10 according to this disclosure, the defects having the width w and the length L which do not satisfy the above-mentioned relational expression (1) can be present even in the region where the transfer pattern is to be formed on the thin film, provided that the number of the defects is equal to or less than a predetermined number. This is because, if the number of the defects which do not satisfy the above-mentioned relational expression (1) is very small, it is possible to prevent the defects from being detected in the mask defect inspection by setting, on the main surface, the position of the transfer pattern to be formed on the thin film so that the defects are covered with the thin film. This is also because it is possible to reduce the effect of the defects on the transferred image. The predetermined number as an allowable number of the defects which do not satisfy the above-mentioned relational expression (1) differs depending on a specification of the transfer mask to be manufactured from the mask blank 10. For example, the number is preferably equal to five, more preferably equal to three, further preferably equal to one.

On the other hand, in the mask blank 10, all of the defects present in the region where the transfer pattern is to be formed on the thin film preferably have the width w and the length L which satisfy the above-mentioned relational expression (1). This is because, by using the mask blank 10 as mentioned above, when the transfer mask of any specification is manufactured, the defects are not detected in the mask defect inspection and the defects do not affect the transferred image.

As described above, even if the convex defects or the concave defects are present on the substrate of the mask blank, the mask blank can be deemed as an acceptable product assuming that the defects do not affect the transferred image, in case where the convex defects or the concave defects satisfy the relational expression (1) between the width w and the length L of the defect. Therefore, the ratio of the mask blanks as acceptable products becomes higher so that the mask blanks are provided at a high yield.

As a method for manufacturing the mask blank according to this disclosure, for example, a manufacturing method as will hereinafter be described is applicable. Specifically, the method is for manufacturing a mask blank comprising a transparent substrate having a main surface on which a thin film for forming a transfer pattern is formed. The method includes a step of preparing the transparent substrate, a step of carrying out defect inspection for the main surface of the transparent substrate on the side where the transfer pattern is to be formed, a step of selecting, as an acceptable product, each transparent substrate without any defect detected in the defect inspection and each transparent substrate only with a defect satisfying a predetermined relationship, and a step of forming the thin film for forming the transfer pattern on one main surface of each transparent substrate as the acceptable product. The defect satisfying the predetermined relationship satisfies the relationship of L≤97.9×w^{-0.4} where w represents the width of the defect as seen from the side of the main surface and L represents the length of the defect from the main surface to an end of the defect in a direction that is perpendicular to the main surface. By using the manufacturing method mentioned above, the ratio of the mask blanks as the acceptable products becomes higher so that the mask blanks can be provided at a high yield.

The relational expression (1) between the width w and the length L of the defect described in connection with the above-mentioned mask blank is similarly applicable to defects present on a substrate of the transfer mask.

A transfer mask according to this disclosure comprises a transparent substrate having a main surface on which a thin film formed with a transfer pattern is provided, and is characterized in that a defect is present on the main surface of the transparent substrate; and the defect satisfies a relationship:

L≤97.9×w^{-0.4}

where w represents a width of the defect as seen from the side of the main surface and L represents a length of the defect from the main surface to an end of the defect in a direction that is perpendicular to the main surface.

Herein, the above-mentioned defects present on the main surface of the substrate include both the convex defects and the concave defects. The above-mentioned length L from the main surface to the end of the defect in the direction that is perpendicular to the main surface is the height h in case of the convex defects and the depth d in case of the concave defects. This is similar to the case of the above-mentioned mask blank.

The above-mentioned transfer mask is manufactured by forming a thin film on a main surface of a transparent substrate to obtain a mask blank and then forming a transfer pattern on the thin film of the mask blank. For example, by forming the transfer pattern on the thin film 2 of the mask blank 10 illustrated in FIG. 1, the transfer mask 20 having the transfer pattern 2a formed on the transparent substrate 1 as illustrated in FIG. 3 is obtained. The mask blank for use in manufacture of the transfer mask is preferably the above-mentioned mask blank of this disclosure. Generally, as a method for forming the transfer pattern on the thin film 2, it is preferable to use a photolithography method in view of fine pattern formation. Materials of the transparent substrate and the thin film in the transfer mask are similar to those in case of the above-mentioned mask blank.

In the transfer mask of this disclosure, the convex defects or the concave defects are present on the substrate of the transfer mask. If the convex defects or the concave defects satisfy the above-mentioned relational expression (1) between the width w and the length L of the defect, the transfer mask can be deemed as an acceptable product assuming that, although the convex defects or the concave defects are present, these defects do not affect a transferred image. The process of deriving the relational expression (1) between the width w and the length L of the defect is as described above.

In the transfer mask according to this disclosure, the length L of the defect is preferably 13 nm or less. If the length L of the defect, i.e., the height h of the convex defect or the depth d of the concave defect, exceeds 13 nm, such defect often fail to satisfy the above-mentioned relational expression (1) between the width w and the length L of the defect. Those defects have a greater effect on the transferred image. Like in case of the mask blank mentioned above, the length L of the defect is more preferably 11 nm or less. This is because, if the length L of the defect is 11 nm or less and the width w of the defect is 200 nm or less, the defect is not detected by the mask defect inspection. Further preferably, the length L of the defect is 6 nm or less. This is because, if the length L of the defect is 6 nm or less and the width w of the defect is 1000 nm or less, the defect is not detected by the mask defect inspection.

In the transfer mask according to this disclosure, the width w of the defect is preferably 200 nm or less. If the width w of the defect exceeds 200 nm, such defect often fails to satisfy the relational expression (1) between the width w and the length L of the defect. Such defect has a greater effect on the transferred image.

In the transfer mask of this disclosure, the above-mentioned defects may be those defects present on the main surface of the transparent substrate in a region where the transfer pattern is formed on the thin film. For example, in case where the transparent substrate has a main surface of a square shape having a side of about 152 mm, the region where the transfer pattern is formed on the thin film is preferably an inside region of a square shape having a side of 132 mm with respect to a center of the main surface of the transparent substrate as a reference. Therefore, even if the defects are present on the main surface of the substrate in the inside region of a square shape having a side of 132 mm with respect to the center of the main surface of the transparent substrate as a reference, the transfer mask can be judged as an acceptable product in the defect inspection in case where the defects satisfy the above-mentioned relational expression (1).

Also in the transfer mask of this disclosure, the defects having the width w and the length L which do not satisfy the above-mentioned relational expression (1) can be present in an outside region around the region where the transfer pattern is formed on the thin film. This is because the outside region around the region where the transfer pattern is formed on the thin film has no substantial effect on the transferred image. On the other hand, all of the defects present in the region where the transfer pattern is formed on the thin film preferably satisfy the above-mentioned relational expression (1).

As described above, in the transfer mask of this disclosure, the convex defects or the concave defects are present on the substrate of the transfer mask. The convex defects or the concave defects satisfy the relational expression (1) between the width w and the length L of the defect. Even if the convex defects or the concave defects are present, the transfer mask can be deemed as an acceptable product assuming that the defects do not affect the transferred image.

This disclosure also provides a method for manufacturing a semiconductor device, including a step of exposure-transferring a transfer pattern onto a resist film on a semiconductor substrate by using the above-mentioned transfer mask. By using the transfer mask obtained according to this disclosure, it is possible to manufacture a high-quality semiconductor device provided with a fine pattern.

### EXAMPLES

Hereinafter, this disclosure will be described more in detail with reference to examples.

### Example 1

Example 1 relates to a mask blank for use in manufacture of a halftone phase shift mask using an ArF excimer laser having a wavelength of 193 nm as exposure light.

A mask blank used in Example 1 has a structure in which a light semi-transmissive film, a light shielding film of a double-layer structure, and a hard mask film are formed as layers on a transparent substrate (glass substrate) in this order. The mask blank was manufactured in the following manner.

As the glass substrate, a synthetic quartz substrate (about 152 mm×152 mm in size×6.35 mm in thickness) was prepared. The synthetic quartz substrate was subjected to defect inspection using M6640 (manufactured by Lasertec) as a mask blank defect inspection apparatus. As a result, on the synthetic quartz substrate in a region where the transfer pattern is to be formed (inside region of a square shape having a side of 132 mm), seven convex defects were detected and four concave defects were detected. For all of the convex defects and the concave defects thus detected, the width w and the height h or the depth d of each of the convex defects and the concave defects were measured by an atomic force microscope (AFM). As a result, it has been confirmed that, for all of the convex defects, the relationship between the width w and the height h satisfied the relationship of h≤97.9×w^{-0.4} and that, for all of the concave defects, the width w and the depth d satisfied the relationship of d≤97.9×w^{-0.4}.

Next, on the synthetic quartz substrate, a MoSiN light semi-transmissive film (phase shift film) consisting of molybdenum, silicon, and nitrogen was formed to a thickness of 69 nm. Specifically, the synthetic quartz substrate was placed in a single-wafer DC sputtering apparatus. Using a sintered target of a mixture of molybdenum (Mo) and silicon (Si) (Mo:Si=12 atomic %:88 atomic %) and a gas mixture of argon (Ar), nitrogen (N₂), and helium (He) (flow rate ratio Ar:N₂:He=8:72:100, pressure=0.2 Pa) as a sputtering gas, a MoSiN light semi-transmissive film was formed by reactive sputtering (DC sputtering). The light semi-transmissive film thus formed had a composition of Mo:Si:N=4.1:35.6:60.3 (atomic % ratio). The composition was measured by X-ray photoelectron spectroscopy (XPS).

Next, the synthetic quartz substrate was taken out from the sputtering apparatus and the light semi-transmissive film on the synthetic quartz substrate was subjected to heat treatment in air. The heat treatment was carried out at 450° C. for 30 minutes. For the light semi-transmissive film after the heat treatment, a transmittance and a phase shift amount at a wavelength (193 nm) of the ArF excimer laser were measured by using a phase shift amount measuring device. As a result, the transmittance was 6.44% and the phase shift amount was 174.3 degrees.

Next, the substrate with the light semi-transmissive film formed thereon was put into the sputtering apparatus again and a light-shielding film having a multilayer structure including a lower layer of a CrOCN film and an upper layer of a CrN film was formed on the light semi-transmissive film. Specifically, by carrying out reactive sputtering using a target of chromium in a gas mixture atmosphere of argon (Ar), carbon dioxide (CO₂), nitrogen (N₂), and helium (He) (flow rate ratio Ar:CO₂:N₂:He=20:24:22:30, pressure 0.3 Pa), the lower layer of the light-shielding film, comprising the CrOCN film having a thickness of 47 nm, was formed on the light semi-transmissive film. Subsequently, by carrying out reactive sputtering similarly using the chromium target in a gas mixture atmosphere of argon (Ar) and nitrogen (N₂) (flow rate ratio Ar:N₂=25:5, pressure 0.3 Pa), the upper layer of the light-shielding film, comprising the CrN film having a thickness of 5 nm, was formed on the lower layer.

The CrOCN film as the lower layer of the light-shielding film thus formed had a composition of Cr:O:C:N=49.2:23.8:13.0:14.0 (atomic % ratio) and the CrN film as the upper layer of the light-shielding film had a composition of Cr: N=76.2:23.8 (atomic % ratio). These compositions were measured by XPS.

Next, on the light-shielding film, a hard mask film comprising a SiON film was formed. Specifically, by carrying out reactive sputtering using a silicon target in a gas mixture atmosphere of argon (Ar), nitrogen monoxide (NO), and helium (He) (flow rate ratio Ar:NO:He=8:29:34, pressure of 0.3 Pa), the hard mask film comprising the SiON film having a thickness of 15 nm was formed on the light-shielding film. The SiON film thus formed had a composition of Si:O:N=37:44:19 (atomic % ratio). The composition was measured by XPS.

The multilayer film comprising the light semi-transmissive film and the light-shielding film had an optical density of 3.0 or more (transmittance of 0.1% or less) at the wavelength (193 nm) of the ArF excimer laser.

In the above-mentioned manner, the mask blank of Example 1 was manufactured.

Next, the above-mentioned mask blank thus manufactured was subjected to defect inspection. As a defect inspection apparatus used in the defect inspection, M6640 (manufactured by Lasertec) as a mask blank defect inspection apparatus was used. As a result, all of the convex defects and the concave defects having been detected by the defect inspection for the synthetic quartz substrate were detected at the same positions of the thin film. However, other convex defects and other concave defects were not newly detected.

Next, using the mask blank, a halftone phase shift mask was manufactured.

At first, an upper surface of the mask blank was subjected to HMDS (hexamethyldisilazane) treatment. By spin coating, a chemically amplified resist for electron beam writing (PRL009 manufactured by Fuji Film Electronic Materials) was applied and subjected to predetermined baking treatment to form a resist film having a film thickness of 150 nm.

Next, using an electron beam writer, a predetermined device pattern was written on the resist film. Thereafter, the resist film was developed to form a resist pattern. The predetermined device pattern is a pattern corresponding to a phase shift pattern to be formed on the light semi-transmissive film (phase shift film) and includes a line-and-space pattern.

Next, using the resist pattern as a mask, the hard mask film was subjected to dry etching to form a hard mask film pattern. As a dry etching gas, a fluorine-based gas (SF₆) was used.

After the resist pattern was removed, the light-shielding film comprising the multilayer film including the upper layer and the lower layer was continuously subjected to dry etching with the hard mask film pattern used as a mask to form a light-shielding film pattern. As a dry etching gas, a gas mixture of Cl₂ and O₂ (Cl₂:O₂=8:1 (flow rate ratio)) was used.

Subsequently, with the light-shielding film pattern used as a mask, the light semi-transmissive film was subjected to dry etching to form a light semi-transmissive film pattern (phase shift film pattern). As a dry etching gas, a fluorine-based gas (SF₆) was used. In this etching step of the light semi-transmissive film, the hard mask film pattern exposed on a surface was removed.

Next, throughout an entire surface on the substrate, the resist film was again formed by spin coating. By using the electron beam writer, a predetermined device pattern (for example, a pattern corresponding to a light-shielding zone pattern) was written. Thereafter, the resist film was developed to form a predetermined resist pattern. Subsequently, using the resist pattern as a mask, the exposed light-shielding film pattern was etched to remove, for example, the light-shielding film pattern in a transfer pattern forming region and to form the light-shielding zone pattern in a peripheral portion of the transfer pattern forming region. As a dry etching gas in this case, a gas mixture of Cl₂ and O₂ (Cl₂:O₂=8:1 (flow rate ratio)) was used.

Finally, the remaining resist pattern was removed to prepare the halftone phase shift mask.

Then, the halftone phase shift mask was subjected to mask defect inspection using the mask defect inspection apparatus Teron (manufactured by KLATencor). As a result, the convex defects and the concave defects on the substrate which have been detected in the defect inspection of the mask blank were not detected as mask defects.

Next, using AIMS193 (manufactured by Carl Zeiss), the halftone phase shift mask was subjected to simulation of a transferred image when exposure transfer was carried out onto a resist film on a semiconductor device with exposure light having a wavelength of 193 nm. An exposure transfer image in the simulation was verified to confirm that the exposure transfer could be carried out with high accuracy. That is, it has been confirmed that, even if the defects are present on the substrate of the mask blank, there arises no problem of an effect on a transferred image that results from the defects as far as the defects satisfy the above-mentioned relationship between the width w and the height h (or the depth d).

### Comparative Example 1

In the manner similar to Example 1, a prepared synthetic quartz substrate (glass substrate) was subjected to defect inspection using M6640 (manufactured by Lasertec) as a mask blank defect inspection apparatus. As a result, on the synthetic quartz substrate in a region where a transfer pattern is to be formed (inside region of a square shape having a side of 132 mm), nine convex defects were detected and six concave defects were detected. For all of the convex defects and the concave defects thus detected, the width w and the height h or the depth d of each of the convex defects and the concave defects were measured by an atomic force microscope (AFM). As a result, it has been confirmed that, among all of the convex defects, seven convex defects do not satisfy the relationship of h≤97.9×w^{-0.4} as the relationship between the width w and the height h and that, among all of the concave defects, three concave defects do not satisfy the relationship of h≤97.9×w^{-0.4} as the relationship between the width w and the depth d.

Next on the transparent substrate (glass substrate) after the defect inspection, a mask blank having a structure in which a light semi-transmissive film, a light-shielding film of a double-layer structure, and a hard mask film were successively formed as layers was manufactured in the manner similar to Example 1.

Next, the above-mentioned mask blank thus manufactured was subjected to defect inspection. As a defect inspection apparatus used in the defect inspection, M6640 (manufactured by Lasertec) as a mask blank defect inspection apparatus similar to that in Example 1 was used. As a result, all of the convex defects and the concave defects which have been detected in the defect inspection for the synthetic quartz substrate were detected at the same positions on the thin film. No other convex defects and concave defects were newly detected.

Next, using the mask blank, a halftone phase shift mask was manufactured in the manner similar to Example 1.

Then, the halftone phase shift mask thus manufactured was subjected to mask defect inspection using the mask defect inspection apparatus Teron (manufactured by KLA Tencor). As a result, the convex defects and the concave defects, 10 in number, were detected as mask defects in the transfer pattern forming region. All of these defects were the defects, among the convex defects and the concave defects having been detected in the defect inspection of the transparent substrate, which did not satisfy the above-mentioned relationship between the width w and the height h (or the depth d). On the other hand, any defect, among the convex defects and the concave defects having been detected in the defect inspection of the transparent substrate, which satisfied the above-mentioned relationship between the width w and the height h (or the depth d) was not detected in the mask defect inspection.

Next, using AIMS193 (manufactured by Carl Zeiss), the halftone phase shift mask was subjected to simulation of a transferred image when exposure transfer was carried out onto a resist film on a semiconductor device with exposure light having a wavelength of 193 nm. An exposure transfer image in the simulation was verified. As a result, transfer failure was caused which results from the convex defects and the concave defects detected by the mask defect inspection. On the other hand, for the convex defects and the concave defects which were detected by the defect inspection of the transparent substrate but which were not detected by the mask defect inspection, no transfer failure was caused.

### EXPLANATION OF REFERENCE NUMERALS

1 transparent substrate

1a to 1i convex defects

2 thin film

2a transfer pattern

2b line pattern

10 mask blank

20 transfer mask

1. A mask blank comprising:
a transparent substrate having a main surface; and
a thin film formed on the main surface and for forming a transfer pattern,
wherein a defect is present on the main surface of the transparent substrate, and the defect satisfies a relationship:
L≤97.9×w^{-0.4}
where w represents a width of the defect as measured along a direction parallel to the main surface of the transparent substrate and L represents a dimension of the defect in a direction that is perpendicular to the main surface of the transparent substrate, wherein the dimension is one among a maximum height of the defect with respect to the main surface of the transparent substrate and a maximum depth of the defect with respect to the main surface of the transparent substrate.

2. The mask blank according to claim 1, wherein the dimension L of the defect is 13 nm or less.

3. The mask blank according to claim 1, wherein the width w of the defect is 200 nm or less.

4. The mask blank according to claim 1, wherein the defect is present on the main surface of the transparent substrate in a region where a transfer pattern is to be formed on the thin film.

5. The mask blank according to claim 1, wherein the defect contains silicon and oxygen.

6. The mask blank according to claim 1, wherein a transmittance of the thin film with respect to exposure light of an ArF excimer laser is 2% or more, and
wherein the thin film is configured to transmit the exposure light so that the exposure light as transmitted by the thin film has a phase difference of 150 degrees or more and 200 degrees or less with respect to the exposure light as transmitted through air for a same distance as a thickness of the thin film.

7. A transfer mask comprising:
a transparent substrate having a main surface; and
a thin film formed on the main surface and provided with a transfer pattern,
wherein a defect is present on the main surface of the transparent substrate, and the defect satisfies a relationship:
L≤97.9×w^{-0.4}
where w represents a width of the defect as measured along a direction parallel to the main surface of the transparent substrate and L represents a dimension of the defect in a direction that is perpendicular to the main surface of the transparent substrate, wherein the dimension is one among a maximum height of the defect with respect to the main surface of the transparent substrate and a maximum depth of the defect with respect to the main surface of the transparent substrate.

8. The transfer mask according to claim 7, wherein the dimension L of the defect is 13 nm or less.

9. The transfer mask according to claim 7, wherein the width w of the defect is 200 nm or less.

10. The transfer mask according to claim 7, wherein the defect is present on the main surface of the transparent substrate in a region where the transfer pattern is formed on the thin film.

11. The transfer mask according to claim 7, wherein the defect contains silicon and oxygen.

12. The transfer mask according to claim 7, wherein a transmittance of the thin film with respect to exposure light of an ArF excimer laser is 2% or more, and
wherein the thin film is configured to transmit the exposure light so that the exposure light as transmitted by the thin film has a phase difference of 150 degrees or more and 200 degrees or less with respect to the exposure light as transmitted through air for a same distance as a thickness of the thin film.

13. A method for manufacturing a semiconductor device, comprising exposure-transferring a transfer pattern to a resist film on a semiconductor substrate by using a transfer mask comprising:
a transparent substrate having a main surface; and
a thin film formed on the main surface and provided with the transfer pattern,
wherein a defect is present on the main surface of the transparent substrate, and the defect satisfies a relationship:
L≤97.9×w^{-0.4}
where w represents a width of the defect as measured along a direction parallel to the main surface of the transparent substrate and L represents a dimension of the defect in a direction that is perpendicular to the main surface of the transparent substrate, wherein the dimension is one among a maximum height of the defect with respect to the main surface of the transparent substrate and a maximum depth of the defect with respect to the main surface of the transparent substrate.

14. The mask blank according to claim 1, wherein the dimension L of the defect is 4 nm or more.

15. The mask blank according to claim 1, wherein the dimension L of the defect is 13 nm or less and the width w of the defect is 200 nm or less, and
wherein the defect is present on the main surface of the transparent substrate in a region where a transfer pattern is to be formed on the thin film.

16. The transfer mask according to claim 7, wherein the dimension L of the defect is 4 nm or more.

17. The transfer mask according to claim 7, wherein the dimension L of the defect is 13 nm or less and the width w of the defect is 200 nm or less, and
wherein the defect is present on the main surface of the transparent substrate in a region where the transfer pattern is formed on the thin film.

18. The method according to claim 13, wherein the dimension L of the defect is 4 nm or more.

19. The method according to claim 13, wherein the dimension L of the defect is 13 nm or less and the width w of the defect is 200 nm or less, and
wherein the defect is present on the main surface of the transparent substrate in a region where the transfer pattern is formed on the thin film.
